(19) United States
(12) Patent Application Publication
(10) Pub. No.: US 2009/0134957 A1
(43) Pub. Date: May 28, 2009

(54) Film bulk acoustic resonator package and method for manufacturing the same

(76) Inventor: Kwang Jae Shin, Gyeonggi-do (KR)

Correspondence Address: THE RAFFERTY PATENT LAW FIRM, 1952 Gallows Road, Suite 200, Vienna, VA, 22182-3823, US

(21) Appl. No.: 12/325,138

(22) Filed: Nov. 28, 2008

(30) Foreign Application Priority Data
Nov. 28, 2007 (KR) 10-2007-0121801

(51) Int. Cl. H03H 9/54; H01R 43/00

(52) U.S. Cl. 333/187; 29/825

(57) ABSTRACT

A film bulky acoustic resonator (FBAR) package and a method for manufacturing the package are provided. A top surface of a FBAR on a substrate is entirely covered with a cap and a signal line connected to an external circuit unit is directly attached to a bonding pad of the FBAR through a substrate via-hole formed through the substrate. Since the signal line connected to the external circuit unit is directly attached to the bonding pad of the FBAR through the substrate via-hole formed through the substrate, a process for attaining a signal line connection space of the external circuit unit can be omitted. Therefore, an overall working process can be simplified and the manufacturing cost can be reduced, while improving the production yield. Furthermore, a size of the FBAR can be remarkably reduced. In addition, as described above, when the signal line connected to the external circuit unit is directly attached to the boding pad through a bottom of the substrate, a length of the signal line can be minimized and thus the deterioration of the FBAR, which may be caused during a wafer level packaging process, can be reduced.

### BACKGROUND OF THE INVENTION

1. Field of the Invention

The present invention relates to a film bulk acoustic resonator (FBAR) package, and more particularly, to an FBAR package that is a kind of high frequency filter for radio communications and a method for manufacturing the FBAR package.

2. Description of the Related Art

An FBAR is a thin film type high frequency filter that is mainly used for radio communication devices using a variety of frequency bands ranging from about 900 MHz to about 10 GHz. As shown in FIG. 1, a typical FBAR 20 includes a lower electrode 21 deposited on a substrate 10 provided with a cavity 11 and a dielectric 12, a piezoelectric layer 22 deposited on the substrate 10, an upper electrode 23, a bonding pad 24 connected to a signal line of an external circuit unit connected to the lower and upper electrodes 21 and 23.

The substrate 10 is formed of silicon (Si), high resistance silicon (HRS), a gallium-arsenic (Ge—As) glass, or ceramic. The dielectric 12 is formed of low temperature oxide, silicon oxide, or nitride silicon (Si_{X}N_{Y})

The lower and upper electrodes 21 and 23 are formed of metal having excellent conductivity, such as molybdenum (Mo), ruthenium (Ru), aluminum (Al), gold (Au), platinum (Pt), tungsten (W), tantalum (Ta), platinum-tantalum (Pt—Ta), titanium (Ti), platinum-titanium (Pt—Ti), and the like.

The piezoelectric layer 22 is formed of aluminum nitride (AlN) or Zinc oxide (ZnO). The bonding pad 224 is mostly formed of gold (Au).

A method for manufacturing the FBAR 20 will be described hereinafter with reference to FIG. 2.

First, when the substrate 10 is provided, a portion of a top surface of the substrate 10 is etched through a photolithography process to thereby form a pit 10a (S10).

Next, poly-silicon, phosphor-silicate glass (PSG), zinc oxide, or polymer is deposited in the pit 10a through a chemical vapor deposition (CVD) process, a sputtering process, or a spin coating process to form a sacrifice layer 10b (S12), after which the dielectric 12 is deposited on the substrate 10, in which the sacrifice layer 10b is formed, through a plasma enhanced DVD process or a sputtering process (S14).

After the dielectric 12 is formed, the lower electrode 21, piezoelectric layer 22, upper electrode 23, and bonding pad 24 are sequentially formed and patterned on the dielectric 12 of the substrate 10 (S16). Subsequently, the sacrifice layer 10b is removed to complete the FBAR 20 shown in FIG. 1.

At this point, the sacrifice layer 10b is removed by an organic solvent such as fluoride xnenon (XeF₂), fluoride bromine (BrF₂), buffered oxide etchant, fluoride hydrogen (HF), and acetone.

After the FBAR 20 is completed as described above, the top surface of the FBAR 20 formed on the substrate 10 is covered with a cap 30 formed of polymer such as a dry film to package the FBAR 20. At this point, a lower end of the cap 30 is attached to the bonding pad 24.

### SUMMARY OF THE INVENTION

However, according to the typical method for packaging the FBAR by attaching the cap 30 formed of the polymer to the top surface of the FBAR 20, as illustrated in the process S20 of FIG. 2, a signal line connection space A for stably connecting a signal line of the external circuit unit, which is connected to the electrodes 21 and 23, to the bonding pad 24 when the lower end of the cap 30 is attached to the bonding pad 24 of the FBAR 20. Therefore, a size of the FBAR 20 increases.

An object of the present invention is to provide an FBAR package in which a top surface of the FBAR on a substrate is entirely covered with a cap and a signal line connected to an external circuit unit is directly attached to a bonding pad of the FBAR through a substrate via-hole formed through the substrate.

Another object of the present invention is to provide a method for manufacturing the FBAR package.

According to an aspect of the present invention, there is provided a film bulky acoustic resonator (FBAR) package including: a substrate; a film bulky acoustic resonator on the substrate; bonding and sealing pads patterned to enclose a top surface of the film bulky acoustic resonator; adhesive layers formed on the respective bonding and sealing pads; a cap attached to the adhesive layers to completely cover the top surface of the film bulky acoustic resonator; and a signal line that is connected to an external circuit unit and is directly attached to the bonding pad of the film bulky acoustic resonator through a substrate via-hole 10c formed through the substrate.

According to another aspect of the present invention, there is provided a method of manufacturing a film bulky acoustic resonator package, the method including: patterning a sealing pad to enclose a film bulky acoustic resonator on a substrate; completely covering a top surface of the film bulky acoustic resonator by attaching a cap to adhesive layers formed on a bonding pad and the sealing pad enclosing the film bulky acoustic resonator on the substrate; forming a substrate via-hole from a bottom surface of the substrate to a bottom surface of the bonding pad of the film bulky acoustic resonator; and directly attaching a signal line connected to an external circuit unit to the bonding pad.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view of a film bulk acoustic resonator (FBAR) according to a related art;

FIG. 2 is a process diagram illustrating a method for manufacturing an FBAR package according to a related art; and

FIG. 3 is a process diagram illustrating a method for manufacturing an FBAR package according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

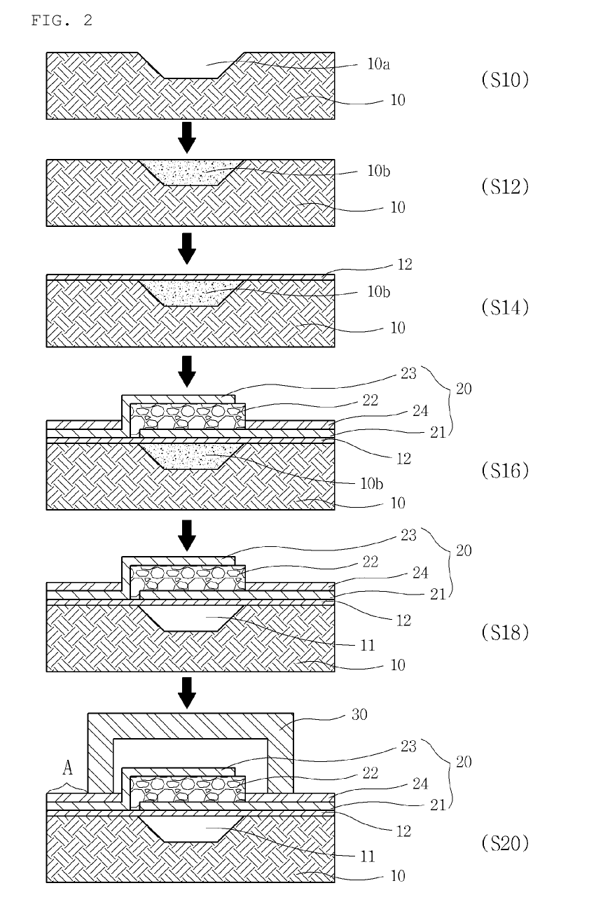

A film bulk acoustic resonator (FBAR) in accordance with an embodiment of the present invention is manufactured through processes S10 to S18 of FIG. 2 and is subsequently packaged.

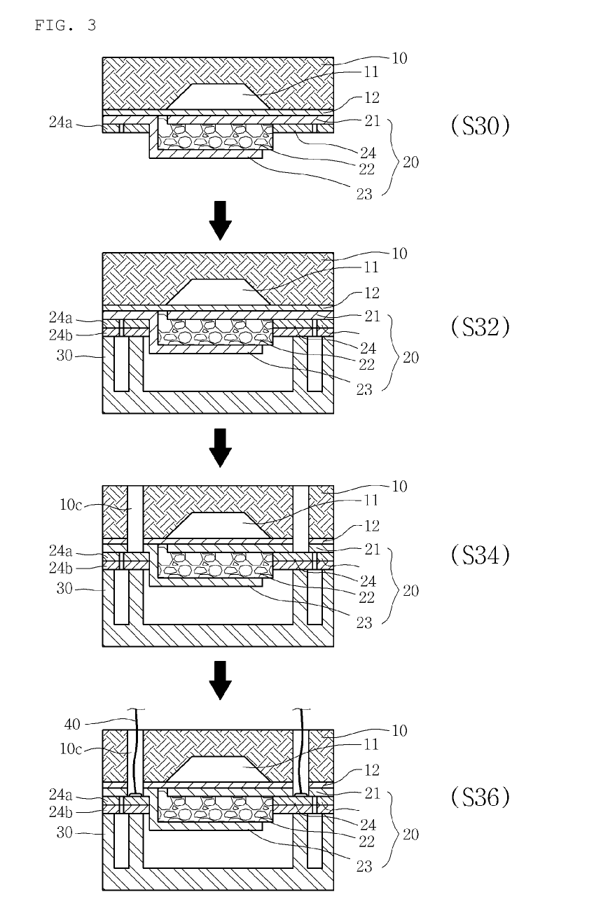

Referring to FIG. 3, an FBAR package in accordance with an embodiment of the present invention includes a FBAR 20 that is formed on a substrate through the process illustrated in FIG. 2. A top surface of the FBAR 20 is completely covered with a cap 30 attached to top adhesive layers 24b that are formed on a bonding pad 24 and a sealing pad 24a. A substrate via-hole 10c is formed through the substrate 10, dielectric 12, and lower and upper electrodes 21 and 23 of the FBAR 20. A signal line 40 connected to an external circuit unit is directly attached to the bonding pad 24 of the FBAR 20 through the via-hole 10c.

The sealing pad 24a is formed of a same material as the bonding pad 24 and patterned together with the bonding pad 24.

The adhesive layers 24b formed on the top surfaces of the bonding pad 24 and sealing pad 24a may be formed of one of tin (Sn), indium (In), and silicon (Si).

The cap 30 is formed in a dual-wall structure having inner and outer walls. The outer and inner walls are respectively attached to the sealing and bonding pads 24a and 24.

The cap 30 may be formed of silicon (Si), high resistance silicon (HRS), glass, ceramic, polymer, and the like.

A method for manufacturing the FBAR package in accordance with an embodiment of the present invention will be described hereinafter.

When the FBAR 20 is manufactured through the processes S10 to S19, the sealing pad 24a is patterned to enclose the FBAR 20 on the substrate 10 (S30). The sealing pad 24a may be patterned together with the bonding pad 24 of the FBAR 20.

When the sealing pad 24a is patterned to enclose together with the bonding pad 24 the FBAR 20 on the substrate 10, the adhesive layers 24b are formed on the bonding and sealing pads 24 and 24a that enclose the FBAR 20 on the substrate 10 and the cap 30 is attached to the adhesive layer 24b to completely cover the top surface of the FBAR 20 (S32).

At this point, the outer and inner walls of the cap 30 are respectively attached to the sealing and boding pads 24a and 24. Particularly, the inner wall attached to the bonding pad 24 functions to support the bonding pad 24 when the substrate via-hole 10c is being formed. The cap 30 may be attached to the adhesive layers 24b on the bonding and sealing pads 24 and 24a through an eutectic welding process using a gold-tin (Au—Sn) alloy.

After the cap 30 is completely attached on the top surface of the FBAR 20, the substrate via-hole 10c is formed from the bottom surface of the substrate 10 to the bottom surface of the bonding pad 24 of the FBAR 20 (S34).

At this point, the substrate via-hole 10c may be formed through a silicon deep etching process or a wet-etching process using potassium hydroxide (KOH) and tetra methyl ammonium hydroxide.

After the substrate via-hole 10c is formed, the signal line 40 connected to the external circuit unit is directly attached to the bonding pad 24 through the substrate via-hole 10c, thereby completing the FBAR package (S36).

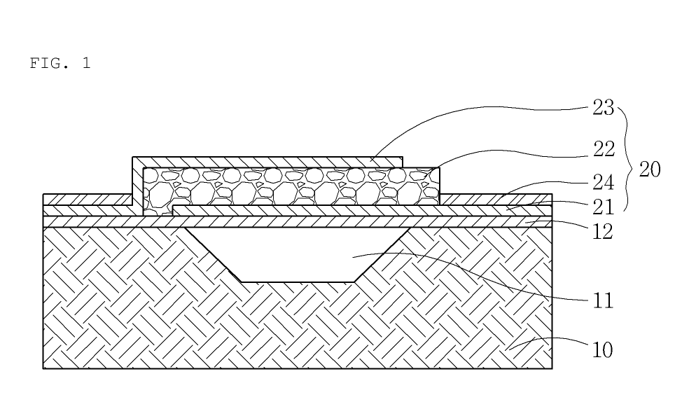

As described above, when the signal line 40 connected to the external circuit unit is directly attached to the bonding pad 24 of the FBAR 20 through the substrate via-hole 10c formed through the substrate 10, a process for attaining a signal line connection space of the external circuit unit, which is illustrated with reference to FIGS. 1 and 2, can be omitted. Therefore, an overall working process can be simplified and the manufacturing cost can be reduced, while improving the production yield. Furthermore, a size of the FBAR 20 can be remarkably reduced.

In addition, as described above, when the signal line 40 connected to the external circuit unit is directly attached to the boding pad 24 through a bottom of the substrate 10, a length of the signal line 40 can be minimized and thus the deterioration of the FBAR, which may be caused during a wafer level packaging process, can be reduced.

According to the present invention, since the signal line connected to the external circuit unit is directly attached to the bonding pad of the FBAR through the substrate via-hole formed through the substrate, a process for attaining a signal line connection space of the external circuit unit can be omitted. Therefore, an overall working process can be simplified and the manufacturing cost can be reduced, while improving the production yield. Furthermore, a size of the FBAR can be remarkably reduced.

In addition, as described above, when the signal line connected to the external circuit unit is directly attached to the boding pad through a bottom of the substrate, a length of the signal line can be minimized and thus the deterioration of the FBAR, which may be caused during a wafer level packaging process, can be reduced.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A film bulky acoustic resonator package comprising:
a substrate 10;
a film bulky acoustic resonator 20 on the substrate 10;
bonding and sealing pads 24 and 24a patterned to enclose a top surface of the film bulky acoustic resonator 20;
adhesive layers 24b formed on the respective bonding and sealing pads 24 and 24a;
a cap 30 attached to the adhesive layers 24b to completely cover the top surface of the film bulky acoustic resonator 20; and
a signal line 40 that is connected to an external circuit unit and is directly attached to the bonding pad 24 of the film bulky acoustic resonator 20 through a substrate via-hole 10c formed through the substrate.

2. The film bulky acoustic resonator of claim 1, wherein the cap 30 is formed of a material selected from the group consisting of silicon, high resistance silicon, glass, and ceramic.

3. A method of manufacturing a film bulky acoustic resonator package, the method comprising:
patterning a sealing pad 24a to enclose a film bulky acoustic resonator 20 on a substrate 10 (S30);
completely covering a top surface of the film bulky acoustic resonator 20 by attaching a cap 30 to adhesive layers 24b formed on a bonding pad 24 and the sealing pad 24a enclosing the film bulky acoustic resonator 20 on the substrate 10 (S32);
forming a substrate via-hole 10c from a bottom surface of the substrate 10 to a bottom surface of the bonding pad 24 of the film bulky acoustic resonator 20 (S34); and
directly attaching a signal line 40 connected to an external circuit unit to the bonding pad 24.
